(19) United States
(12) Patent Application Publication
(10) Pub. No.: US 2025/0240877 A1
(43) Pub. Date: Jul. 24, 2025

(54) WIRING CIRCUIT BOARD

(71) Applicant: NITTO DENKO CORPORATION, Osaka (JP)

(72) Inventors: Takashi YAMAMOTO, Osaka (JP); Makiko HIRATA, Osaka (JP)

(73) Assignee: NITTO DENKO CORPORATION, Osaka (JP)

(21) Appl. No.: 19/025,069

(22) Filed: Jan. 16, 2025

(30) Foreign Application Priority Data
Jan. 22, 2024 (JP) 2024-007689
Dec. 17, 2024 (JP) 2024-221106

(51) Int. Cl. H05K 1/02; H05K 1/05

(52) U.S. Cl. CPC H05K 1/0271; H05K 1/05; H05K 2201/09227; H05K 2201/09236; H05K 2201/09281; H05K 2201/09481; H05K 2201/09727

(57) ABSTRACT

A wiring circuit board includes a plurality of wiring portions, a first support portion supporting one end portion of each of the wiring portions, and a second support portion supporting the other end portion of each of the wiring portions. Each of the wiring portions and has a wire. The wire has a first portion connected to the first support portion, a second portion connected to the second support portion, and a body portion disposed between the first portion and the second portion. The first portion and the second portion are thinner than the body portion.

### CROSS-REFERENCE TO RELATED APPLICATION

The present application claims priority from Japanese Patent Application No. 2024-7689 filed on Jan. 22, 2024, and priority from Japanese Patent Application No. 2024-221106 filed on Dec. 17, 2024, the contents of both of which are hereby incorporated by reference into this application.

### TECHNICAL FIELD

The present invention relates to a wiring circuit board.

### BACKGROUND ART

Conventionally, there has been a known wiring circuit board including a plurality of wiring portions spaced from each other at intervals, and a connecting portion that connects the plurality of wiring portions (for example, see Patent document 1 below).

In the wiring circuit board, the thickness of the wiring portion is larger than (more than twice) the width of the wiring portion. Therefore, the wiring portion can easily be moved in the width direction as compared with in the thickness direction.

### CITATION LIST

### Patent Document

Patent Document 1: Japanese Unexamined Patent Publication No. 2019-212656

### SUMMARY OF THE INVENTION

### Problem to be Solved by the Invention

In the wiring circuit board as described in Patent Document 1, when the wiring portion is moved, there is a possibility that stress is concentrated in the vicinity of the end portion (that is a portion connected to the connecting portion) of the wiring portion. Therefore, there is a possibility that a crack occurs in the wire in the vicinity of the end portion of the wiring portion. The present invention provides a wiring circuit board capable of suppressing the occurrence of a crack in the wire in the vicinity of the end portion of the wiring portion.

### Means for Solving the Problem

The present invention [1] includes a wiring circuit board including: a plurality of wiring portions extending in a first direction and spaced from each other at an interval; and a first support portion supporting one end portion of each of the plurality of wiring portions in the first direction, wherein each of the plurality of wiring portions has a wire extending in the first direction, wherein the wire includes: a body portion disposed away from the first support portion in the first direction; and a first portion disposed between the first support portion and the body portion in the first direction, the first portion connected to the first support portion, and wherein the first portion is thinner than the body portion.

According to such a configuration, in the wire disposed in the wiring portion, the first portion connected to the first support portion is thinner than the body portion.

Therefore, when the wiring portion is moved, it is possible to suppress the stress in the vicinity of one end portion of the wiring portion being concentrated in the wire. In other words, it is possible to relax the stress on the wire disposed in the vicinity of one end portion of the wiring portion.

As a result, it is possible to suppress the occurrence of a crack in the wire in the vicinity of one end portion of the wiring portion.

The present invention [2] includes the wiring circuit board described in the above-described [1], wherein each of the plurality of wiring portions has a plurality of the wires, and wherein in all of the wires, the first portion is thinner than the body portion.

According to such a configuration, it is possible to suppress the occurrence of a crack in the first portion in all of the wires.

The present invention [3] includes the wiring circuit board described in the above-described [1] or [2], wherein the wire includes: a first conductor layer; and a second conductor layer disposed on the first conductor layer, and wherein the first conductor layer of the first portion is thinner than the first conductor layer of the body portion.

According to such a configuration, it is possible to suppress the occurrence of a crack in the first conductor layer of the first portion.

The present invention [4] includes the wiring circuit board described in the above-described [1] or [2], wherein the wire includes: a first conductor layer; and a second conductor layer disposed on the first conductor layer, and wherein the second conductor layer of the first portion is thinner than the second conductor layer of the body portion.

According to such a configuration, it is possible to suppress the occurrence of a crack in the second conductor layer of the first portion.

The present invention [5] includes the wiring circuit board described in the above-described [1] or [2], wherein the wire includes: a first conductor layer; and a second conductor layer disposed on the first conductor layer, and wherein the first conductor layer of the first portion is thinner than the first conductor layer of the body portion, and the second conductor layer of the first portion is thinner than the second conductor layer of the body portion. According to such a configuration, it is possible to suppress the occurrence of a crack in the first conductor layer of the first portion, and also suppress the occurrence of a crack in the second conductor layer of the first portion.

The present invention [6] includes the wiring circuit board described in any one of the above-described [1] to [5], wherein a length of the first portion is 0.1% to 25% of a total length of the wire disposed in the wiring portion in the first direction.

According to such a configuration, the stress on the wire disposed in the vicinity of one end portion of the wiring portion can be further relaxed.

As a result, it is possible to further suppress the occurrence of a crack in the wire in the vicinity of one end portion of the wiring portion.

The present invention [7] includes the wiring circuit board described in any one of the above-described [1] to [6], wherein a width of the first portion is 50% or more and less than 100% of a width of the body portion.

According to such a configuration, the stress on the wire disposed in the vicinity of one end portion of the wiring portion can be further relaxed.

As a result, it is possible to further suppress the occurrence of a crack in the wire in the vicinity of one end portion of the wiring portion.

The present invention [8] includes the wiring circuit board described in any one of the above-described [1] to [7], wherein the wiring circuit board includes: a metal supporting layer; an insulating layer disposed at one side of the metal supporting layer in the thickness direction of the metal supporting layer; and a conductive pattern disposed at one side of the insulating layer in the thickness direction and having the wire, and wherein the metal supporting layer is disposed in the first support portion and the wiring portion.

The present invention [9] includes the wiring circuit board described in any one of the above-described [1] to [7], wherein the wiring circuit board includes: a metal supporting layer; an insulating layer disposed at one side of the metal supporting layer in the thickness direction of the metal supporting layer; and a conductive pattern disposed at one side of the insulating layer in the thickness direction and having the wire, and wherein the metal supporting layer is not disposed in the wiring portion, but disposed in the first support portion.

The present invention [10] includes the wiring circuit board described in any one of the above-described [1] to [9], further including: a second support portion supporting an other end portion of each of the plurality of wiring portions in the first direction, wherein the wire further includes: a second portion disposed between the second support portion and the body portion in the first direction, the second portion connected to the second support portion, and wherein the second portion is thinner than the body portion.

According to such a configuration, in the wire disposed in the wiring portion, the second portion connected to the second support portion is thinner than the body portion.

Therefore, when the wiring portion is moved, it is possible to suppress the stress in the vicinity of the other end portion of the wiring portion being concentrated in the wire. In other words, it is possible to relax the stress on the wire disposed in the vicinity of the other end portion of the wiring portion.

As a result, it is possible to suppress the occurrence of a crack in the wire in the vicinity of the other end portion of the wiring portion.

The present invention [11] includes the wiring circuit board described in the above-described [10], wherein each of the plurality of wiring portions has a plurality of the wires, and wherein in all of the wires, the second portion is thinner than the body portion.

According to such a configuration, it is possible to suppress the occurrence of a crack in the second portion in all the wires.

The present invention [12] includes the wiring circuit board described in the above-described or [11], wherein the wire includes: a first conductor layer; and a second conductor layer disposed on the first conductor layer, and wherein the first conductor layer of the second portion is thinner than the first conductor layer of the body portion.

According to such a configuration, it is possible to suppress the occurrence of a crack in the first conductor layer of the second portion.

The present invention [13] includes the wiring circuit board described in the above-described or [11], wherein the wire includes: a first conductor layer; and a second conductor layer disposed on the first conductor layer, and wherein the second conductor layer of the second portion is thinner than the second conductor layer of the body portion.

According to such a configuration, it is possible to suppress the occurrence of a crack in the second conductor layer of the second portion.

The present invention [14] includes the wiring circuit board described in the above-described or [11], wherein the wire includes: a first conductor layer; and a second conductor layer disposed on the first conductor layer, and wherein the first conductor layer of the second portion is thinner than the first conductor layer of the body portion, and the second conductor layer of the second portion is thinner than the second conductor layer of the body portion. According to such a configuration, it is possible to suppress the occurrence of a crack in the first conductor layer of the second portion, and also suppress the occurrence of a crack in the second conductor layer of the second portion.

The present invention [15] includes the wiring circuit board described in any one of the above-described to [14], wherein a length of the second portion is 0.1% to 25% of a total length of the wire disposed in the wiring portion in the first direction.

According to such a configuration, the stress on the wire disposed in the vicinity of the other end portion of the wiring portion can be further relaxed.

As a result, it is possible to further suppress the occurrence of a crack in the wire in the vicinity of the other end portion of the wiring portion.

The present invention [16] includes the wiring circuit board described in any one of the above-described to [15], wherein a width of the second portion is 50% or more and less than 100% of a width of the body portion.

According to such a configuration, the stress on the wire disposed in the vicinity of the other end portion of the wiring portion can be further relaxed.

As a result, it is possible to further suppress the occurrence of a crack in the wire in the vicinity of the other end portion of the wiring portion.

The present invention [17] includes the wiring circuit board described in any one of the above-described to [16], wherein the wiring circuit board includes: a metal supporting layer; an insulating layer disposed at one side of the metal supporting layer in the thickness direction of the metal supporting layer; and a conductive pattern disposed at one side of the insulating layer in the thickness direction and having the wire, and wherein the metal supporting layer is disposed in the first support portion, the second support portion, and the wiring portion.

The present invention [18] includes the wiring circuit board described in any one of the above-described to [16], wherein the wiring circuit board includes: a metal supporting layer; an insulating layer disposed at one side of the metal supporting layer in the thickness direction of the metal supporting layer; and a conductive pattern disposed at one side of the insulating layer in the thickness direction and having the wire, and wherein the metal supporting layer is not disposed in the wiring portion, but disposed in the first support portion and the second support portion.

### Effects of the Invention

According to the wiring circuit board of the present invention, it is possible to suppress the occurrence of a crack in the wire in the vicinity of the end portion of the wiring portion.

### BRIEF DESCRIPTION OF THE DRAWINGS

FIG. 1 shows a plan view of a wiring circuit board as one embodiment of the present invention.

FIG. 2 is a cross-sectional view of the wiring circuit board shown in FIG. 1, taken along line A-A.

FIG. 3 is a cross-sectional view of the wiring circuit board shown in FIG. 1, taken along line B-B.

FIG. 4 is an explanatory view for explaining a modified example (1).

FIG. 5 is an explanatory view for explaining a modified example (2), and shows an example in which the first conductor layer is thinned in the first portion and the second portion of the wire.

FIG. 6 is an explanatory view for explaining the modified example (2), and shows an example in which the second conductor layer is thinned in the first portion and the second portion of the wire.

FIG. 7 is an explanatory view for explaining the modified example (2), and shows an example in which both of the first conductor layer and the second conductor layer are thinned in the first portion and the second portion of the wire.

FIG. 8 is an explanatory view for explaining a modified example (3).

FIG. 9 is an explanatory view for explaining a modified example (4).

FIG. 10 is an explanatory view for explaining a modified example (5).

FIG. 11 is an explanatory view for explaining a modified example (6).

FIG. 12 is a cross-sectional view of the wiring circuit board shown in FIG. 11, taken along line C-C.

FIG. 13 is an explanatory view for explaining a modified example (7).

FIG. 14 is an explanatory view for explaining a modified example (8).

FIG. 15 is an explanatory view for explaining a modified example (9).

FIGS. 16A and 16B are explanatory views for explaining a modified example (10).

FIG. 17 is an explanatory view for explaining a modified example (11).

### DESCRIPTION OF THE EMBODIMENT

### 1. Wiring Circuit Board

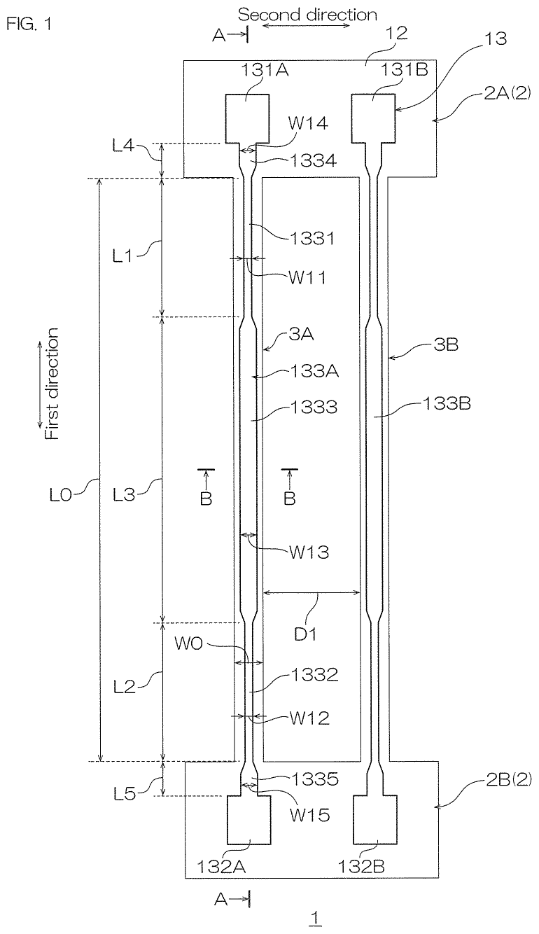

As shown in FIG. 1, the wiring circuit board 1 includes a plurality of support portions 2 (a first support portion 2A and a second support portion 2B), and a plurality of wiring portions 3A and 3B.

The first support portion 2A and the second support portion 2B are spaced from each other at an interval in a first direction. The first direction is a direction in which a wire 133A to be described later extends. The first direction is perpendicular to a thickness direction of the wiring circuit board 1. Each of the first support portion 2A and the second support portion 2B extends in a second direction. The second direction is perpendicular to both the first direction and the thickness direction. The first support portion 2A supports one end portion of each of the wiring portions 3A and 3B in the first direction. Terminals 131A and 131B of a conductive pattern 13 to be described later are disposed in the first support portion 2A. The second support portion 2B supports the other end portion of each of the wiring portions 3A and 3B in the first direction. The terminals 132A and 132B of the conductive pattern 13 to be described later are disposed in the second support portion 2B.

The wiring portions 3A and 3B are disposed between the first support portion 2A and the second support portion 2B in the first direction. In the present embodiment, each of the wire portions 3A and 3B extends in the first direction. The one end portion of each of the wiring portions 3A and 3B in the first direction is connected to the first support portion 2A. The other end portion of each of the wiring portions 3A and 3B in the first direction is connected to the second support portion 2B. The shape of each of the wiring portions 3A and 3B is not limited. Each of the wiring portions 3A and 3B may have a linear shape or be curved. The wiring portions 3A and 3B are arranged in the second direction. In other words, the wiring portions 3A and 3B are arranged in a direction perpendicular to the direction in which the wiring portion 3A extends. The wiring portions 3A and 3B are spaced from each other at an interval in the second direction. In other words, the wiring portions 3A and 3B are disposed away from each other at an interval in a direction perpendicular to the direction in which the wiring portion 3A extends. At least a portion of the wire 133A of the conductive pattern 13 to be described later is disposed in the wiring portion 3A. At least a portion of a wire 133B of the conductive pattern 13 to be described later is disposed in the wiring portion 3B.

The width W0 of the wiring portion 3A is, for example, 5 μm to 300 μm, preferably 10 μm to 250 μm.

The “width” is a length in a direction perpendicular to both of the direction in which the wiring portions extend and the thickness direction. For example, the “width” of the wiring portion 3A is a length in a direction perpendicular to both of the direction in which the wiring portion 3A extends and the thickness direction. In the present embodiment, the “width” is a length in the second direction.

An interval D1 between the wiring portion 3A and the wiring portion 3B is, for example, 5 μm to 300 μm, preferably 10 μm to 250 μm.

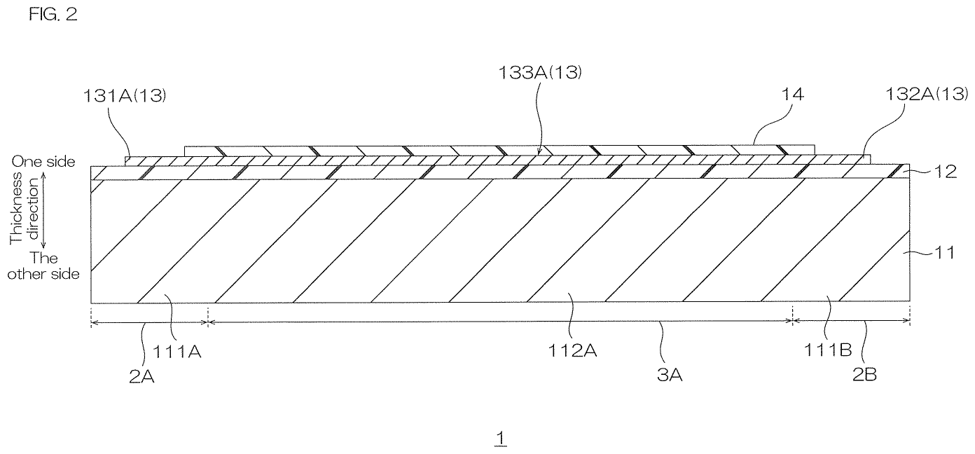

As shown in FIG. 2, the wiring circuit board includes a metal supporting layer 11, a first insulating layer 12, a conductive pattern 13, and a second insulating layer 14.

### (1) Metal Supporting Layer

The metal supporting layer 11 is disposed in the support portion 2 (the first support portion 2A and the second support portion 2B) and the wiring portions 3A and 3B. That is, the support portion 2 (the first support portion 2A and the second support portion 2B) and the wiring portions 3A and 3B have the metal supporting layer 11. The metal supporting layer 11 supports the first insulating layer 12, the conductive pattern 13, and the second insulating layer 14. The metal supporting layer 11 is made of metal. Examples of the material of the metal supporting layer 11 include, for example, copper, nickel, cobalt, iron, and the alloys thereof. Examples of the alloy include a copper alloy. As the material of the metal supporting layer 11, preferably, a copper alloy is used.

A thickness T1 of the metal supporting layer 11 is, for example, 10 μm to 300 μm, and preferably 50 μm to 250 μm.

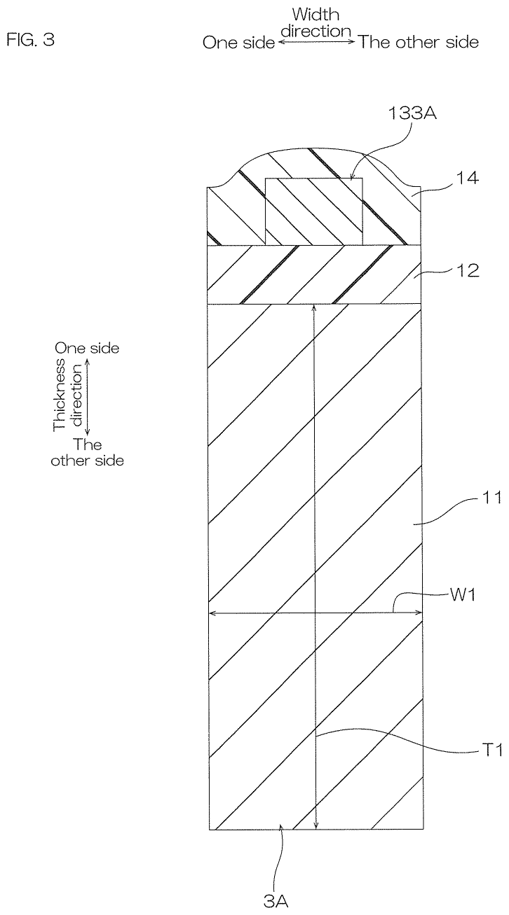

As shown in FIG. 3, the width W1 of the metal supporting layer 11 of the wiring portion 3A is, for example, 5 μm to 300 μm, preferably 10 μm to 250 μm.

The width W1 of the metal supporting layer 11 of the wiring portion 3A may be the same as or different from the width W0 of the wiring portion 3A (see FIG. 1). Specifically, the width W1 of the metal supporting layer 11 of the wiring portion 3A may be the same as or different from the width of the first insulating layer of the wiring portion 3A.

For example, when the width W1 of the metal supporting layer 11 of the wiring portion 3A is larger than the width of the first insulating layer of the wiring portion 3A, and is the largest among the layers forming the wiring portion 3A, the width W1 of the metal supporting layer 11 of the wiring portion 3A is the width W0 of the wiring portion 3A. That is, in this case, the width W1 of the metal supporting layer 11 of the wiring portion 3A is the same as the width W0 of the wiring portion 3A.

Further, for example, when the width of the first insulating layer of the wiring portion 3A is larger than the width W1 of the metal supporting layer 11 of the wiring portion 3A, and is the largest among the layers forming the wiring portion 3A, the width of the first insulating layer 12 of the wiring portion 3A is the width W0 of the wiring portion 3A. In this case, the width W1 of the metal supporting layer 11 of the wiring portion 3A is smaller than the width W0 of the wiring portion 3A.

With respect to the width W1 of the metal supporting layer 11 of the wiring portion 3A, the ratio (T1/W1) of the thickness T1 of the metal supporting layer 11 of the wiring portion 3A is 2 or more, preferably 3 or more. Hereinafter, the ratio (T1/W1) is defined as the aspect ratio of the metal supporting layer 11 of the wiring portion 3A.

When the aspect-ratio (T1/W1) of the metal supporting layer 11 of the wiring portion 3A is the above-described lower limit or more, the stiffness of the wiring portion 3A in the thickness direction can be ensured.

The aspect ratio (T1/W1) of the metal supporting layer 11 of the wiring portion 3A is, for example, 30 or less, preferably 10 or less.

The aspect-ratio (T1/W1) of the metal supporting layer 11 of the wiring portion 3A may be 2 to 30, or 3 to 10.

The interval D2 between the metal supporting layer 11 of the wiring portion 3A and the metal supporting layer 11 of the wiring portion 3B is, for example, 5 μm to 300 μm, preferably 10 μm to 250 μm. The interval D2 may be the same as or different from the interval D1.

### (2) First Insulating Layer

As shown in FIG. 2, the first insulating layer 12 is disposed in the support portion 2 (the first support portion 2A and the second support portion 2B) and in the wiring portions 3A and 3B. That is, the support portion 2 (the first support portion 2A and the second support portion 2B) and the wiring portions 3A and 3B have the first insulating layer 12. The first insulating layer 12 is disposed at one side of the metal supporting layer 11 in the thickness direction of the metal supporting layer 11. The first insulating layer 12 is disposed on one surface of the metal supporting layer 11 in the thickness direction. The first insulating layer 12 is disposed between the metal supporting layer 11 and the conductive pattern 13 in the thickness direction. The first insulating layer 12 insulates the metal supporting layer 11 from the conductive pattern 13. The first insulating layer 12 is made of resin. Examples of the resin include polyimide, maleimide, epoxy resin, polybenzoxazole, and polyester.

### (3) Conductive Pattern

The conductive pattern 13 is disposed at one side of the first insulating layer 12 in the thickness direction. The conductive pattern 13 is disposed on one surface of the first insulating layer 12 in the thickness direction. That is, the wires 133A and 133B are disposed on the first insulating layer 12. The conductive pattern 13 is disposed at an opposite side to the metal supporting layer 11 with respect to the first insulating layer 12 in the thickness direction. The shape of the conductive pattern 13 is not limited.

As shown in FIG. 1, the conductive pattern 13 has a plurality of terminals 131A and 131B, a plurality of terminals 132A and 132B, and a plurality of wires 133A and 133B.

The terminals 131A and 131B are disposed in the first support portion 2A. Each of the terminals 131A and 131B has a square land shape. The terminals 131A and 131B are arranged in the second direction. The terminals 131A and 131B are spaced from each other at an interval in the second direction.

The terminals 132A and 132B are disposed in the second support portion 2B. Each of the terminals 132A and 132B has a square land shape. The terminals 132A and 132B are arranged in the second direction. The terminals 132A and 132B are spaced from each other at an interval in the second direction.

The wire 133A electrically connects the terminal 131A and the terminal 132A. One end portion of the wire 133A is connected to the terminal 131A. The other end portion of the wire 133A is connected to the terminal 132A. At least a portion of the wire 133A is disposed in the wiring portion 3A. That is, the wiring portion 3A has a wire 133A. The wire 133A extends in the first direction.

The wire 133B electrically connects the terminal 131B and the terminal 132B. One end portion of the wire 133B is connected to the terminal 131B. The other end portion of the wire 133B is connected to the terminal 132B. At least a portion of the wire 133B is disposed in the wiring portion 3B. That is, the wiring portion 3B has a wire 133B. The wire 133B extends in the first direction. The wires 133A and 133B are arranged in the second direction. The wires 133A and 133B are spaced from each other at an interval in the second direction.

### (4) Second Insulating Layer

As shown in FIG. 2, the second insulating layer 14 covers all of the wires 133A and 133B. The second insulating layer 14 is disposed on the first insulating layer 12 in the thickness direction. The second insulating layer 14 does not cover the terminals 131A, 131B, 132A, and 132B. The second insulating layer 14 is made of resin. Examples of the resin include polyimide, maleimide, epoxy resin, polybenzoxazole, and polyester.

### 2. Details of Wiring

Next, referring to FIG. 1, the details of the wire 133A are described. The wire 133B has the same structure as that of the wire 133A. The description of the wire 133B is omitted.

As shown in FIG. 1, the wire 133A has a first portion 1331, a second portion 1332, a body portion 1333 (third portion), a fourth portion 1334, and a fifth portion 1335. The wire 133A may not have a fourth portion 1334 and a fifth portion 1335.

The first portion 1331, the second portion 1332, and the body portion 1333 are disposed on the wiring portion 3A. The first portion 1331, the second portion 1332, and the body portion 1333 are disposed between the first support portion 2A and the second support portion 2B in the first direction.

The first section 1331 is disposed in one end portion of the wire portion 3A and in the vicinity thereof in the first direction. The first portion 1331 is disposed between the first support portion 2A and the body portion 1333 in the first direction. The first portion 1331 is connected to the first support portion 2A. Specifically, one end portion of the first portion 1331 in the first direction is connected to the fourth portion 1334 of the wire 133A. When the wire 133A does not have a fourth portion 1334, the one end portion of the first portion 1331 in the first direction may be connected to the terminal 131A. The first portion 1331 is thinner than the body portion 1333.

In the first direction, a length L1 of the first portion 1331 is, for example, 0.1% to 25%, preferably 5% to 25%, more preferably 10% to 25%, more preferably 10% to 21% of a total length L0 of the wire 133A disposed in the wiring portion 3A.

When the length L1 of the first portion 1331 falls within the above-described range, it is possible to further relax the stress on the first portion 1331 while suppressing the increase in the impedance of the wire 133A.

The width W11 of the first portion 1331 is, for example, 50% or more and less than 100%, preferably 60% to 80% of the width W13 of the body portion 1333.

When the width W11 of the first portion 1331 falls within the above-described range, the stress on the first portion 1331 can further be relaxed.

With respect to the width W1 of the metal supporting layer 11 of the wiring portion 3A, the ratio (W11/W1) of the width W11 of the first portion 1331 is, for example, 200% or less, preferably 120% or less. The ratio (W11/W1) is, for example, 50% or more.

When the ratio (W11/W1) falls within the above-described range, the stress on the first part 1331 can further be relaxed.

With respect to the width W0 of the wiring portion 3A, a ratio (W11/W0) of the width W11 of the first portion 1331 is, for example, less than 100%, preferably 70% or less. The ratio (W11/W0) is, for example, 50% or more.

When the ratio (W11/W0) falls within the above-described range, the stress on the first part 1331 can further be relaxed.

The second section 1332 is disposed in the other end portion of the wiring portion 3A and in the vicinity thereof in the first direction. The second portion 1332 is disposed between the second support portion 2B and the body portion 1333 in the first direction. The second portion 1332 is connected to the second support portion 2B. Specifically, one end portion of the second portion 1332 in the first direction is connected to the fifth portion 1335 of the wire 133A. When the wire 133A does not have the fifth portion 1335, the one end portion of the second portion 1332 in the first direction may be connected to the terminal 132A. The second portion 1332 is thinner than the body portion 1333. The width of the second portion 1332 may be the same as the width of the first portion 1331.

In the first direction, a length L2 of the second portion 1332 is, for example, 0.1% to 25%, preferably 5% to 25%, more preferably 10% to 25%, more preferably 10% to 21% of the total length L0 of the wire 133A disposed in the wiring portion 3A.

When the length L2 of the second portion 1332 falls within the above-described range, the stress on the second portion 1332 can further be relaxed.

A width W12 of the second portion 1332 is, for example, 50% or more and less than 100%, preferably 60% to 80% of the width W13 of the body portion 1333.

When the width W12 of the second portion 1332 falls within the above range, the stress in the second portion 1332 can further be relaxed.

With respect to the width W1 of the metal supporting layer 11 of the wiring portion 3A, the ratio (W12/W1) of the width W12 of the second portion 1332 is, for example, 200% or less, preferably 120% or less. The ratio (W12/W1) is, for example, 50% or more.

When the ratio (W12/W1) falls within the above-described range, the stress on the second portion 1332 can further be relaxed.

With respect to the width W0 of the wiring portion 3A, a ratio (W12/W0) of the width W12 of the second portion 1332 is, for example, less than 100%, and preferably 70% or less. The ratio (W12/W0) is, for example, 50% or more.

When the ratio (W12/W0) is within the above-described range, the stress on the second portion 1332 can further be relaxed.

The body portion 1333 is disposed between the first support portion 2A and the second support portion 2B in the first direction. The body portion 1333 is disposed away from the first support portion 2A and the second support portion 2B in the first direction. The body portion 1333 is disposed between the first portion 1331 and the second portion 1332 in the first direction. One end portion of the body portion 1333 in the first direction is connected to the first portion 1331. The other end portion of the body portion 1333 in the first direction is connected to the second portion 1332.

The fourth portion 1334 is disposed in the first support portion 2A. One end portion of the fourth portion 1334 in the first direction is connected to the terminal 131A. The other end portion of the fourth portion 1334 in the first direction is connected to the first portion 1331. A width of the fourth portion 1334 may be the same as the width of the body portion 1333.

The fifth portion 1335 is disposed in the second support portion 2B. One end portion of the fifth portion 1335 in the first direction is connected to the second portion 1332. The other end portion of the fifth portion 1335 in the first direction is connected to the terminal 132A. A width of the fifth portion 1335 may be the same as the width of the body portion 1333.

### 2. Operations and Effects

(1) According to the wiring circuit board 1, as shown in FIG. 1, in the wire 133A disposed in the wiring portion 3A, the first portion 1331 connected to the first support portion 2A and the second portion 1332 connected to the second support portion 2B are thinner than the body portion 1333 disposed between the first portion 1331 and the second portion 1332.

Therefore, when the wiring portion 3A is moved, it is possible to suppress the stress in the vicinity of the end portions of the wiring portion 3A being concentrated in the first portion 1331 and second portion 1332. In other words, it is possible to relax the stress on the wire 133A disposed in the vicinity of the end portions of the wiring portion 3A.

Consequently, it is possible to suppress the occurrence of a crack in the wire 133A in the vicinity of the end portions of the wiring portion 3A.

(2) According to the wiring circuit board 1, as shown in FIG. 1, the length L1 of the first portion 1331 and the length L2 of the second portion 1332 are 0.1% to 25% of the total length L0 of the wire 133A disposed in the wiring portion 3A.

Therefore, the stress on the first portion 1331 and the second portion 1332 can further be relaxed.

Consequently, it is possible to further suppress the occurrence of a crack in the wire 133A in the vicinity of the end portions of the wiring portion 3A.

(3) According to the wiring circuit board 1, as shown in FIG. 1, the width W11 of the first portion 1331 and the width W12 of the second portion 1332 are 50% or more and less than 100% of the width W13 of the body portion 1333.

Therefore, the stress on the first portion 1331 and the second portion 1332 can further be relaxed.

Consequently, it is possible to further suppress the occurrence of a crack in the wire 133A in the vicinity of the end portions of the wiring portion 3A.

### 3. Modified Examples

Next, modified examples are described. In the modified examples, the same members as in the above-described embodiment are given the same reference numerals, and the descriptions thereof are omitted.

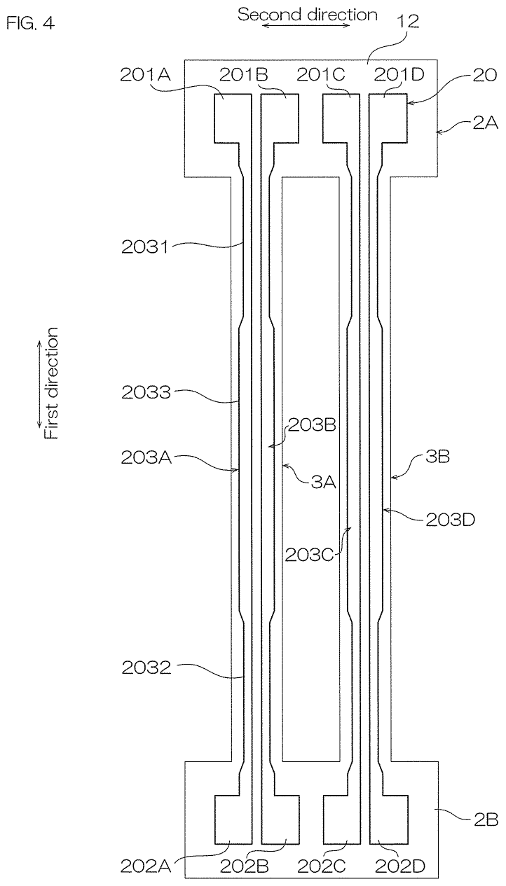

(1) As shown in FIG. 4, each of the wiring portions 3A and 3B may have a plurality of wires 201. Specifically, the wiring circuit board 1 has a conductive pattern 20 in place of the conductive pattern 13. The conductive pattern 20 has a plurality of terminals 201A, 201B, 201C, and 201D, a plurality of terminals 202A, 202B, 202C, and 202D, and a plurality of wires 203A, 203B, 203C, and 203D

The terminals 201A, 201B, 201C, and 201D are disposed in the first support portion 2A. The terminals 201A, 201B, 201C, and 201D are arranged in the second direction. The terminals 201A, 201B, 201C, and 201D are spaced apart from each other at intervals in a second direction.

The terminals 202A, 202B, 202C, and 202D are disposed in the second support portion 2B. The terminals 202A, 202B, 202C, and 202D are arranged in the second direction. The terminals 202A, 202B, 202C, and 202D are spaced apart from each other at intervals in the second direction.

The wire 203A electrically connects the terminal 201A and the terminal 202A. The wire 203B electrically connects the terminal 201B and the terminal 202B. The wires 203A and 203B are arranged in the second direction. The wires 203A and 203B are spaced apart from each other at an interval in the second direction. The wire 203A and the wire 203B are disposed in the wiring portion 3A.

The wire 203C electrically connects the terminal 201C and the terminal 202C. The wire 203D electrically connects the terminal 201D and the terminal 202D. The wires 203C and 203D are arranged in the second direction. The wires 203C and 203D are spaced from each other at an interval in the second direction. The wire 203C and the wire 203D are disposed in the wiring portion 3B.

In all of the wires 203A, 203B, 203C, and 203D, the first portion 2031 and the second portion 2032 are thinner than the body portion 2033.

According to this modified example, it is possible to suppress the occurrence of a crack in all the wires 203A, 203B, 203C, and 203D.

(2) The wiring portion 3A may have a plurality of conductor layers (e.g., a first conductor layer 30A and a second conductor layer 30B).

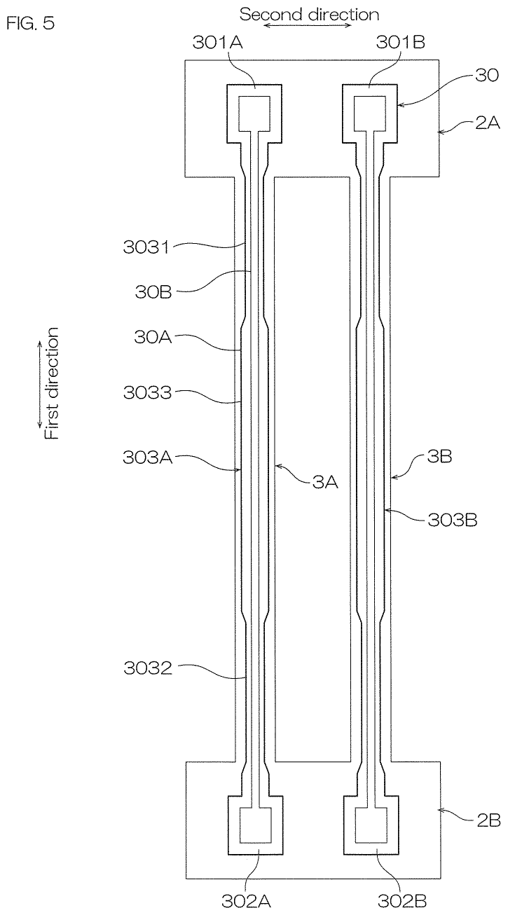

For example, as shown in FIG. 5, the conductive pattern 30 may have a first conductor layer 30A and a second conductor layer 30B. In other words, the wire 303A has a first conductor layer 30A and a second conductor layer 30B. The first conductor layer 30A is disposed on the first insulating layer 12. The second conductor layer 30B is disposed on the first conductor layer 30A.

The first conductor layer 30A of the first portion 3031 and the second portion 3032 may be thinner than the first conductor layer 30A of the body portion 3033. When the first conductor layer 30A of the first portion 3031 and the second portion 3032 is thinner than the first conductor layer 30A of the body portion 3033, it is possible to suppress the occurrence of a crack in the first conductor layer 30A of the first portion 3031 and the second portion 3032.

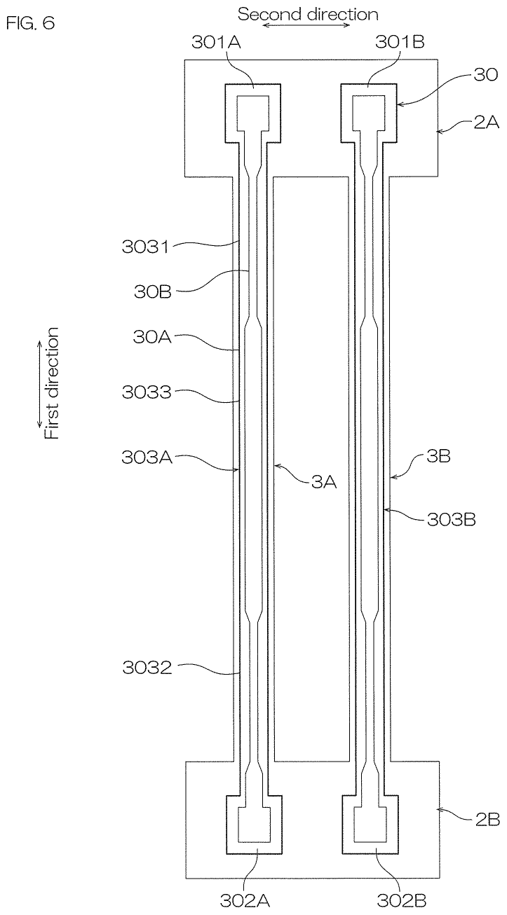

Further, as shown in FIG. 6, the second conductor layer 30B of the first portion 3031 and the second portion 3032 may be thinner than the second conductor layer 30B of the body portion 3033. When the second conductor layer 30B of the first portion 3031 and the second portion 3032 is thinner than the second conductor layer 30B of the body portion 3033, it is possible to suppress the occurrence of a crack in the second conductor layer 30B of the first portion 3031 and the second portion 3032.

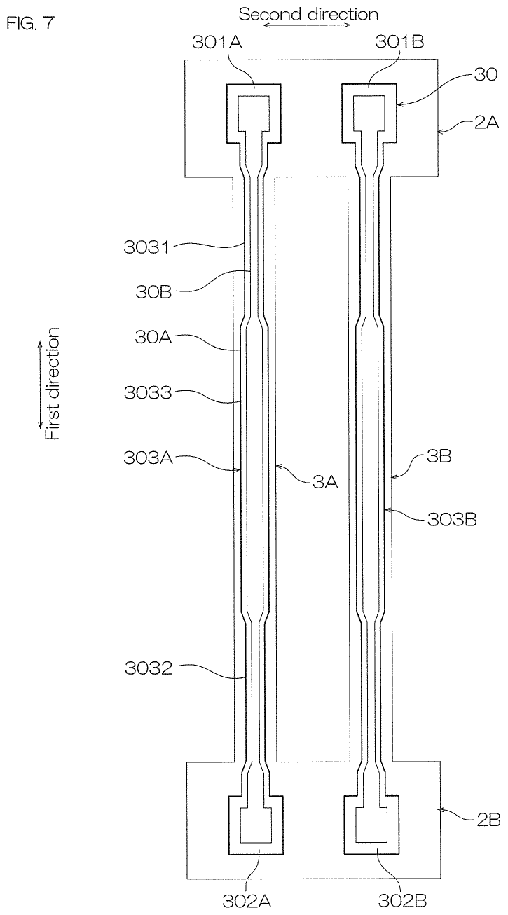

Further, as shown in FIG. 7, it may be that the first conductor layer 30A of the first portion 3031 and the second portion 3032 is thinner than the first conductor layer 30A of the body portion 3033, and the second conductor layer 30B of the first portion 3031 and the second portion 3032 is thinner than the second conductor layer 30B of the body portion 3033. In this case, it is possible to suppress the occurrence of a crack in the first conductor layer 30A and also the occurrence of a crack in the second conductor layer 30B in the first portion 3031 and second portion 3032.

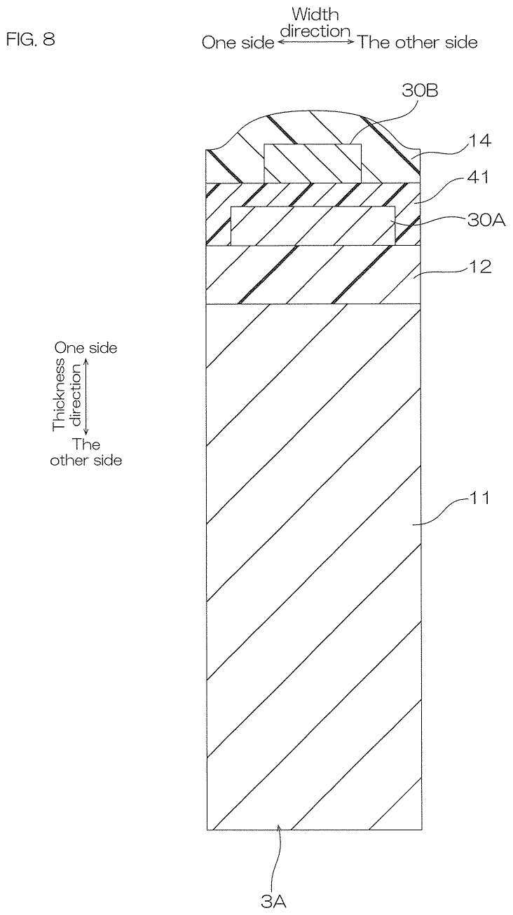

(3) As shown in FIG. 8, the wiring portion 3A may have an intermediate insulating layer 41 between the first conductor layer 30A and the second conductor layer 30B. The intermediate insulating layer 41 is disposed on the first insulating layer 12. The intermediate insulating layer 41 covers the first conductor layer 30A. The second insulating layer 14 is disposed on the intermediate insulating layer 41. The second insulating layer 14 covers the second conductor layer 30B. The first conductor layer 30A is, for example, a signal wire, and the second conductor layer 30B is, for example, a shield conductor layer.

Also in this modified example, as in the above-described modified example (2), the first conductor layer 30A of the first portion 3031 and the second portion 3032 may be thinner than the first conductor layer 30A of the body portion 3033. Further, the second conductor layer 30B of the first portion 3031 and the second portion 3032 may be thinner than the second conductor layer 30B of the body portion 3033.

Also in this modified example, the same operations and effects as in the above-described modified example (2) can be obtained.

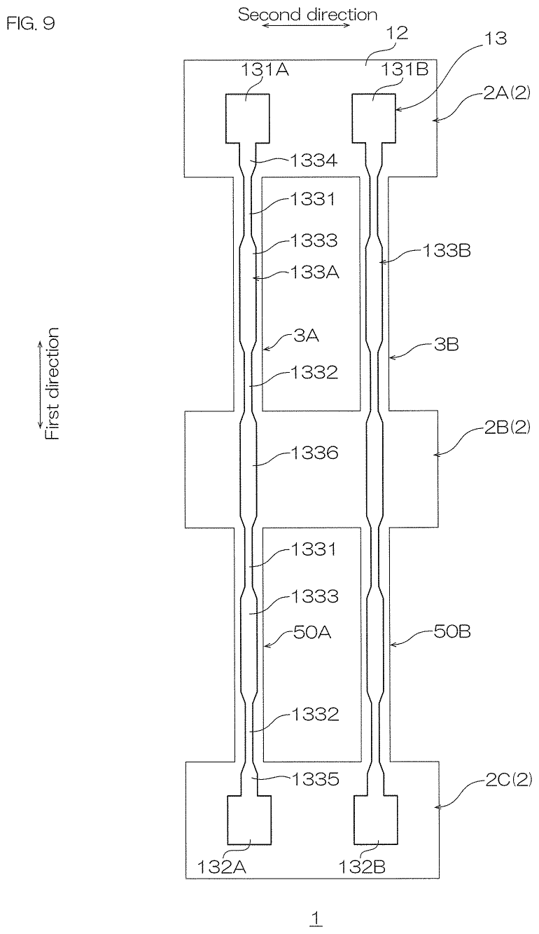

(4) The wiring circuit board 1 may have 3 or more support portions 2. For example, as shown in FIG. 9, the wiring circuit board 1 may have a third support portion 2C and a plurality of wiring portions 50A and 50B in addition to the above-described first support portion 2A, second support portion 2B, and plurality of wiring portions 3A and 3B.

In this case, the terminals 132A and 132B are not disposed in the second support portion 2B but disposed in the third support portion 2C. Each of the wires 133A and 133B extends from the first support portion 2A through the second support portion 2B to the third support portion 2C. The middle portion (sixth portion 1336) of each of the wires 133A and 133B is disposed in the second support portion 2B.

The third support portion 2C is disposed at an opposite side to the first support portion 2A with respect to the second support portion 2B in the first direction. In other words, the second support portion 2B is disposed between the first support portion 2A and the third support portion 2C in the first direction. The third support portion 2C extends in the second direction. The third support portion 2C supports the other end portion of each of the wiring portions 50A and 50B in the first direction. One end portion of each of the wiring portions 50A and 50B in the first direction is supported by the second support portion 2B.

The wiring portion 50A has the same structure as that of the wiring portion 3A. Specifically, the wire 133A disposed in the wiring portion 50A has a first portion 1331, a second portion 1332, and a body portion 1333 in the same manner as the wire 133A disposed in the wiring portion 3A does. Also in the wiring portion 50A, the first portion 1331 and the second portion 1332 are thinner than the body portion 1333.

In the wiring portion 50A, the first portion 1331 is disposed at one end portion of the wiring portion 50A in the first direction. In the first direction, the first portion 1331 in the wire portion 50A is disposed between the second support portion 2B and the body portion 1333, and is connected to the second support portion 2B. Specifically, the first portion 1331 in the wiring portion 50A is connected to the sixth portion 1336.

In the wiring portion 50A, the second portion 1332 is disposed in the other end portion of the wiring portion 50A in the first direction. In the first direction, the second portion 1332 in the wire portion 50A is disposed between the body portion 1333 and the third support portion 2C, and is connected to the third support portion 2C. Specifically, the second portion 1332 in the wiring portion 50A is connected to the fifth portion 1335.

Also in this modified example, it is possible to obtain the same operations and effects as in the above-described embodiment.

Further, in this modified example, the middle portions (sixth portions 1336) of the wires 133A and 133B can be supported by the second support portion 2B.

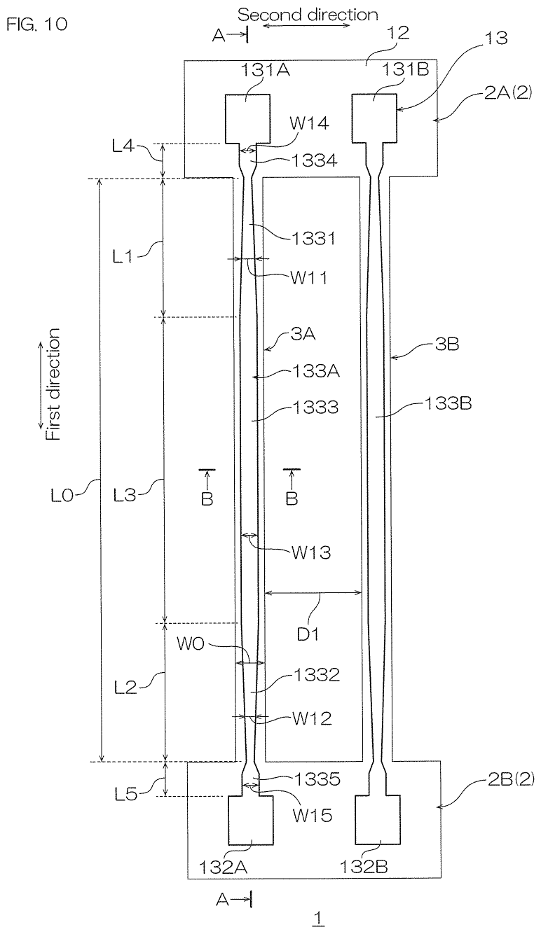

(5) As shown in FIG. 10, the first portion 1331 may be a tapered shape where the width W11 gradually narrows as it approaches the first support portion 2A from the body portion 1333. The second portion 1332 may be a tapered shape where the width W12 gradually narrows as it approaches the second support portion 2B from the body portion 1333.

Also in this modified example, it is possible to obtain the same operations and effects as in the above-described embodiment.

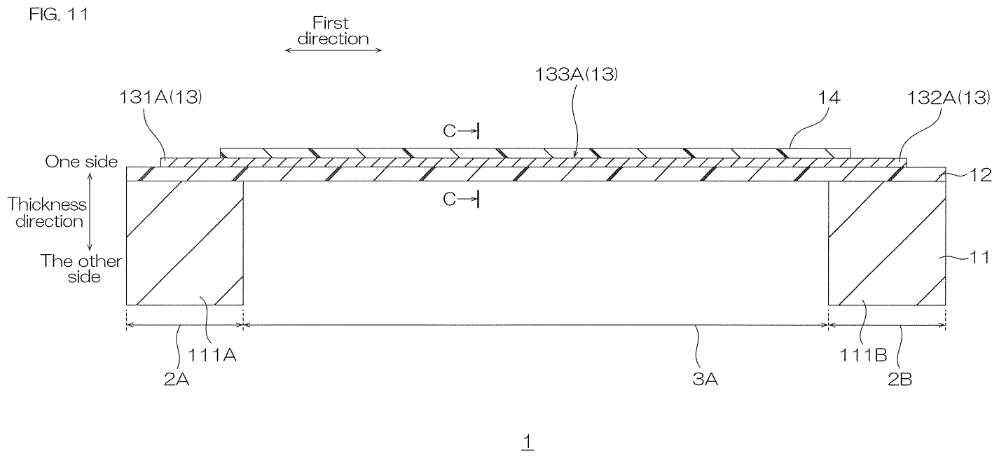

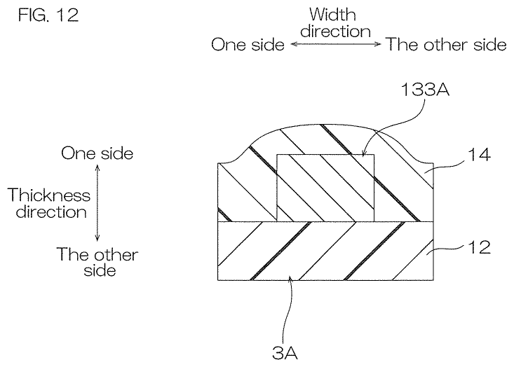

(6) As shown in FIG. 11, the metal supporting layer 11 may not be disposed in the wiring portion 3A, but be disposed in the first support portion 2A and the second support portion 2B. In this case, as shown in FIG. 12, the wiring portion 3A does not have the metal supporting layer 11, but has the first insulating layer 12, the wire 133A, and the second insulating layer 14.

Also in this modified example, it is possible to obtain the same operations and effects as in the above-described embodiment.

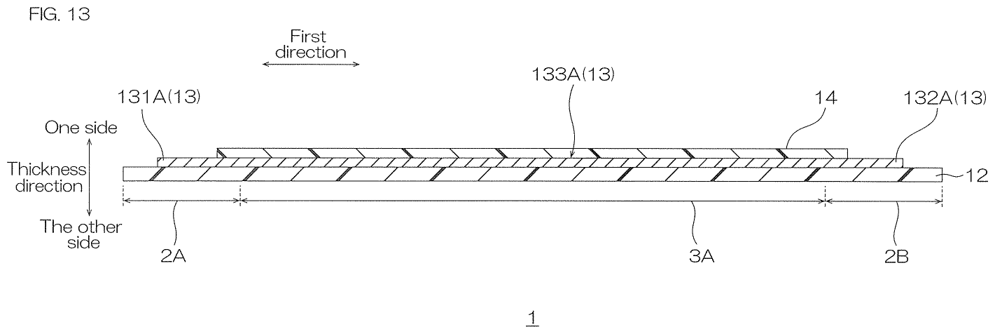

(7) As shown in FIG. 13, the wiring circuit board 1 may not include a metal supporting layer 11. In other words, the support portion 2 (the first support portion 2A and the second support portion 2B) and the wiring portions 3A and 3B may not have a metal supporting layer 11.

Also in this modified example, it is possible to obtain the same operations and effects as in the above-described embodiment.

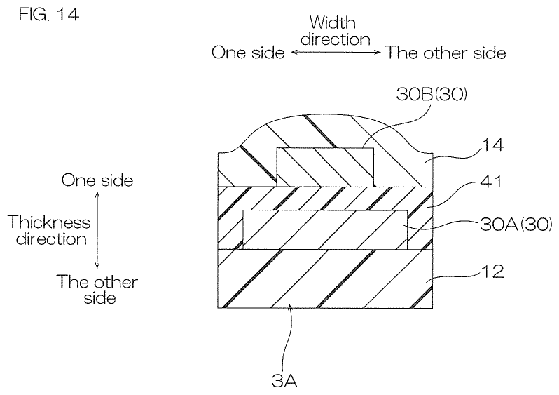

(8) As shown in FIG. 14, when the conductive pattern 30 includes a plurality of conductor layers (for example, a first conductor layer 30A and a second conductor layer 30B), and an intermediate insulating layer 41 disposed between the first conductor layer 30A and the second conductor layer 30B, the wiring portion 3A may not have a metal supporting layer 11.

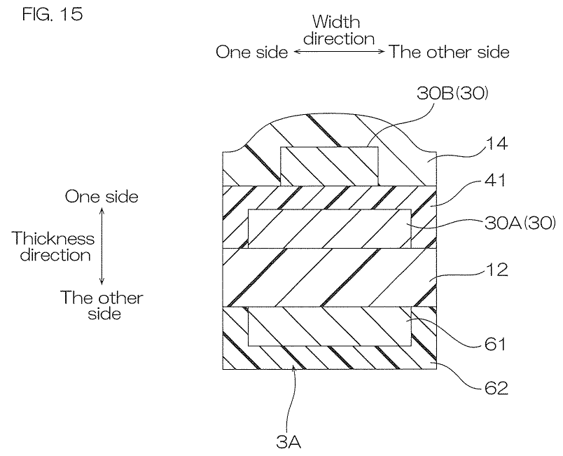

(9) As shown in FIG. 15, the wiring circuit board 1 may include a second conductive pattern 61 and a third insulating layer 62.

The second conductive pattern 61 is disposed at the other side of the first insulating layer 12 in the thickness direction. The second conductive pattern 61 is disposed on the other surface of the first insulating layer 12 in the thickness direction. The second conductive pattern 61 is disposed at an opposite side to the conductive pattern 30 with respect to the first insulating layer 12.

The third insulating layer 62 covers the second conductive pattern 61. The third insulating layer 62 is disposed at the other side of the first insulating layer 12 in the thickness direction. The third insulating layer 62 is disposed on the other surface of the first insulating layer 12 in the thickness direction.

Also in this modified example, it is possible to obtain the same operations and effects as in the above-described embodiment. Further, also in this modified example, the wiring portion 3A may not include a metal supporting layer 11.

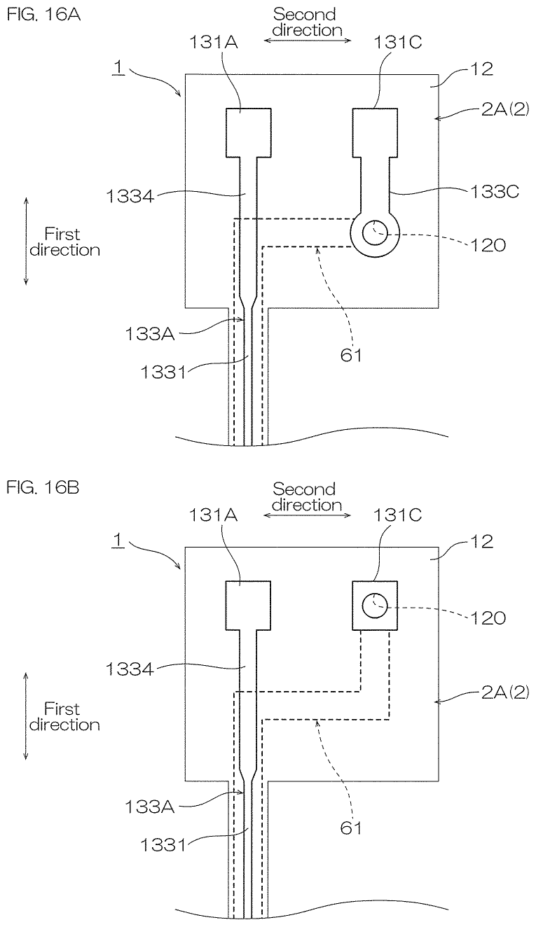

(10) As shown in FIGS. 16A and 16B, when the wiring circuit board 1 includes a second conductive pattern 61, the wiring circuit board 1 may have a terminal 131C electrically connected to the second conductive pattern 61.

In detail, as shown in FIG. 16A, the wiring circuit board 1 may include a terminal 131C and a wire 133C.

The terminal 131C is disposed in the first support portion 2A. The terminal 131C is disposed on the first insulating layer 12. The terminal 131C is disposed on one surface of the first insulating layer 12 in the thickness direction.

The wire 133C is disposed in the first support portion 2A. The wire 133C is disposed away from the wire 133A. The wire 133C is disposed on the first insulating layer 12. The wire 133C is disposed on one surface of the first insulating layer 12 in the thickness direction. One end portion of the wire 133C is connected to the terminal 131C. The other end portion of the wire 133C is connected to the second conductive pattern 61 through a penetrating hole 120 (via hole) of the first insulating layer 12. In this manner, the terminal 131C is electrically connected to the second conductive pattern 61 through the wire 133C.

As shown in FIG. 16B, the terminal 131C may directly be connected to the second conductive pattern 61 through the penetrating hole 120 (via hole) of the first insulating layer 12. In this case, the wiring circuit board 1 does not include a wire 133C.

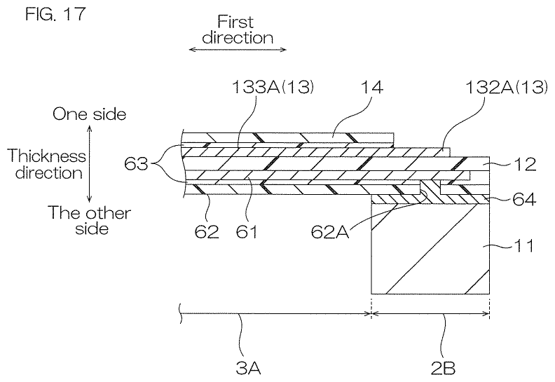

(11) As shown in FIG. 17, the second insulating layer 14 may be bonded to the one surface of the first insulating layer 12 in the thickness direction and the conductive pattern 13 by an adhesive 63.

Furthermore, when the wiring circuit board 1 includes a second conductive pattern 61 and a third insulating layer 62, the third insulating layer 62 may be bonded to the other surface of the first insulating layer 12 in the thickness direction and the second conductive pattern 61 by the adhesive 63.

Furthermore, when the wiring circuit board 1 includes a second conductive pattern 61 and a third insulating layer 62, the wiring circuit board 1 may have a metal supporting layer 11. The metal supporting layer 11 may not be disposed in wiring portion 3A, but be disposed in the first support portion 2A and the second support portion 2B. The metal supporting layer 11 is bonded to the third insulating layer 62 by an adhesive 64. The adhesive 64 is an electrically conductive adhesive, and may be in contact with the second conductive pattern 61 through a penetrating hole 62A of the third insulating layer 62. The second conductive pattern 61 may be electrically connected to the metal supporting layer 11 through the adhesive 64 (electrically conductive adhesive).

Also in this modified example, it is possible to obtain the same operations and effects as in the above-described embodiment.

### EXAMPLES

Next, the present invention is described based on Example and Comparative Example. The present invention is not limited to Examples below. The specific numeral values used in the description below, such as physical property values and parameters, can be replaced with the corresponding physical property values and parameters in the above-described “DESCRIPTION OF THE EMBODIMENTS”, including the upper limit values (numeral values defined with “or less” or “less than”) or the lower limit values (numeral values defined with “or more” or “more than”).

The maximum stresses of the simulation models of the wiring portions of the following Examples and Comparative Examples were calculated by Ansys Mechanical (Finite Element Method Analysis Software, manufactured by ANSYS, Inc.).

### (1) Example

As shown in FIG. 1, a simulation model (a width W0 of the wiring portion: 100 μm, a width W1 of the metal supporting layer: 40 μm, a width W11 of the first portion: 40 μm, a width W12 of the second portion: 40 μm, a width W13 of the body portion: 55 μm, a length L0 of the wiring portion: 500 μm, a length L1 of the first portion: 100 μm, a length L2 of the second portion: 100 μm, a length L3 of the body portion: 300 μm) in which the width of both end portions (the first portion and the second portion) of the wire disposed in the wiring portion was set to be narrower than the width of the portion (the body portion) between the first portion and the second portion was prepared. The maximum stresses on the first portion and second portion of the wire were 75 MPa. Copper was used as the material of the wire, and the elastic modulus of the wire was set to 100 GPa.

### (2) Comparative Example

Except that the widths of the first portion and the second portion were changed, in the same manner as in Example, a simulation model of a wiring in which the first portion, the second portion, and the body portion had the same width (the width W0 of the wiring portion: 100 μm, the width W1 of the metal supporting layer: 40 μm, the width of the wiring: 55 μm) was prepared. The maximum stresses on the first portion and second portion of the wire were 100 MPa.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### DESCRIPTION OF REFERENCE NUMERALS

1 Wiring circuit board
2A First support portion
2B Second support portion
3A Wiring portion
3B Wiring portion
133A Wire
133B Wire
1331 First portion
1332 Second portion
1333 Body portion

1. A wiring circuit board comprising:
a plurality of wiring portions extending in a first direction and spaced from each other at an interval; and
a first support portion supporting one end portion of each of the plurality of wiring portions in the first direction,
wherein each of the plurality of wiring portions has a wire extending in the first direction,
wherein the wire includes:
a body portion disposed away from the first support portion in the first direction; and
a first portion disposed between the first support portion and the body portion in the first direction, the first portion connected to the first support portion, and
wherein the first portion is thinner than the body portion.

2. The wiring circuit board according to claim 1,
wherein each of the plurality of wiring portions has a plurality of the wires, and
wherein in all of the wires, the first portion is thinner than the body portion.

3. The wiring circuit board according to claim 1,
wherein the wire includes:
a first conductor layer; and
a second conductor layer disposed on the first conductor layer, and
wherein the first conductor layer of the first portion is thinner than the first conductor layer of the body portion.

4. The wiring circuit board according to claim 1,
wherein the wire includes:
a first conductor layer; and
a second conductor layer disposed on the first conductor layer, and
wherein the second conductor layer of the first portion is thinner than the second conductor layer of the body portion.

5. The wiring circuit board according to claim 1,
wherein the wire includes:
a first conductor layer; and
a second conductor layer disposed on the first conductor layer, and
wherein the first conductor layer of the first portion is thinner than the first conductor layer of the body portion, and the second conductor layer of the first portion is thinner than the second conductor layer of the body portion.

6. The wiring circuit board according to claim 1,
wherein a length of the first portion is 0.1% to 25% of a total length of the wire disposed in the wiring portion in the first direction.

7. The wiring circuit board according to claim 1,
wherein a width of the first portion is 50% or more and less than 100% of a width of the body portion.

8. The wiring circuit board according to claim 1,
wherein the wiring circuit board includes:
a metal supporting layer;
an insulating layer disposed at one side of the metal supporting layer in the thickness direction of the metal supporting layer; and
a conductive pattern disposed at one side of the insulating layer in the thickness direction and having the wire, and
wherein the metal supporting layer is disposed in the first support portion and the wiring portion.

9. The wiring circuit board according to claim 1,
wherein the wiring circuit board includes:
a metal supporting layer;
an insulating layer disposed at one side of the metal supporting layer in the thickness direction of the metal supporting layer; and
a conductive pattern disposed at one side of the insulating layer in the thickness direction and having the wire, and
wherein the metal supporting layer is not disposed in the wiring portion, but disposed in the first support portion.

10. The wiring circuit board according to claim 1, further comprising:
a second support portion supporting an other end portion of each of the plurality of wiring portions in the first direction,
wherein the wire further includes:
a second portion disposed between the second support portion and the body portion in the first direction, the second portion connected to the second support portion, and
wherein the second portion is thinner than the body portion.

11. The wiring circuit board according to claim 10,
wherein each of the plurality of wiring portions has a plurality of the wires, and
wherein in all of the wires, the second portion is thinner than the body portion.

12. The wiring circuit board according to claim 10,
wherein the wire includes:
a first conductor layer; and
a second conductor layer disposed on the first conductor layer, and
wherein the first conductor layer of the second portion is thinner than the first conductor layer of the body portion.

13. The wiring circuit board according to claim 10,
wherein the wire includes:
a first conductor layer; and
a second conductor layer disposed on the first conductor layer, and
wherein the second conductor layer of the second portion is thinner than the second conductor layer of the body portion.

14. The wiring circuit board according to claim 10,
wherein the wire includes:
a first conductor layer; and
a second conductor layer disposed on the first conductor layer, and
wherein the first conductor layer of the second portion is thinner than the first conductor layer of the body portion, and the second conductor layer of the second portion is thinner than the second conductor layer of the body portion.

15. The wiring circuit board according to claim 10,
wherein a length of the second portion is 0.1% to 25% of a total length of the wire disposed in the wiring portion in the first direction.

16. The wiring circuit board according to claim 10,
wherein a width of the second portion is 50% or more and less than 100% of a width of the body portion.

17. The wiring circuit board according to claim 10,
wherein the wiring circuit board includes:
a metal supporting layer;
an insulating layer disposed at one side of the metal supporting layer in the thickness direction of the metal supporting layer; and
a conductive pattern disposed at one side of the insulating layer in the thickness direction and having the wire, and
wherein the metal supporting layer is disposed in the first support portion, the second support portion, and the wiring portion.

18. The wiring circuit board according to claim 10,
wherein the wiring circuit board includes:
a metal supporting layer;
an insulating layer disposed at one side of the metal supporting layer in the thickness direction of the metal supporting layer; and
a conductive pattern disposed at one side of the insulating layer in the thickness direction and having the wire, and
wherein the metal supporting layer is not disposed in the wiring portion, but disposed in the first support portion and the second support portion.
